(19) United States
(12) Patent Application Publication
(10) Pub. No.: US 2026/0367119 A1
(43) Pub. Date: Nov. 19, 2026

(54) POWER RECEIVER

(71) Applicant: TOYODA GOSEI CO., LTD., Kiyosu-shi (JP)

(72) Inventors: Atsushi SUGIHARA, Kiyosu-shi (JP); Tomokazu SAKAI, Kiyosu-shi (JP)

(21) Appl. No.: 19/647,426

(22) Filed: Apr. 14, 2026

(30) Foreign Application Priority Data
May 15, 2025 (JP) 2025-082195

(51) Int. Cl. G01R 19/25; H02J 50/10; H02J 50/40; H02J 50/80

(52) U.S. Cl. CPC G01R 19/2513; H02J 50/10; H02J 50/402; H02J 50/80

(57) ABSTRACT

A power receiver includes a power receiving antenna that receives a power transfer signal transmitted from a power transmitter, a rectifier circuit that converts AC input power output from the power receiving antenna based on the power transfer signal into DC received power, a conversion unit that converts the received power output from the rectifier circuit so as to be suitable for control in a subsequent stage, a measurement unit that measures received-power voltage of the received power output from the rectifier circuit, a switching unit that switches between electrical connection and disconnection of the rectifier circuit and the conversion unit, and a power reception control unit that estimates the input power based on the received-power voltage that is measured by the measurement unit when the rectifier circuit and the conversion unit are disconnected.

### CROSS-REFERENCE TO RELATED APPLICATIONS

The present patent application claims the priority of Japanese patent application No. 2025/082195 filed on May 15, 2025, and the entire contents of Japanese patent application No. 2025/082195 are hereby incorporated by reference.

### TECHNICAL FIELD

The present invention relates to a power receiver.

### BACKGROUND ART

A power receiving device is known which includes a main rectifier circuit unit that rectifies high-frequency AC received power and outputs it to a load, a sub-rectifier circuit unit connected in parallel with a power receiving unit of the main rectifier circuit unit, and a measurement unit that measures power of an output unit of the sub-rectifier circuit unit (see, e.g., Patent Literature 1).

The power receiving device further includes an estimation unit that estimates output power of the main rectifier circuit unit based on a measurement result of the measurement unit.

### CITATION LIST

### Patent Literature

Patent Literature 1: WO 2023/162288

### SUMMARY

The power receiving device measures power that is a portion of the high-frequency AC received power rectified by the sub-rectifier circuit unit. Therefore, power consumption increases due to insertion loss caused by inserting the sub-rectifier circuit unit into the high-frequency transmission line and due to use of the received power.

It is an object of the invention to provide a power receiver capable of estimating received input power while suppressing power consumption.

One aspect of the invention provides a power receiver, comprising:
a power receiving antenna that receives a power transfer signal transmitted from a power transmitter;
a rectifier circuit that converts AC input power output from the power receiving antenna based on the power transfer signal into DC received power;
a conversion unit that converts the received power output from the rectifier circuit so as to be suitable for control in a subsequent stage;
a measurement unit that measures received-power voltage of the received power output from the rectifier circuit;
a switching unit that switches between electrical connection and disconnection of the rectifier circuit and the conversion unit; and
a power reception control unit that estimates the input power based on the received-power voltage that is measured by the measurement unit when the rectifier circuit and the conversion unit are disconnected.

### ADVANTAGEOUS EFFECTS OF INVENTION

According to an exemplary embodiment of the invention, it is possible to estimate received input power while suppressing power consumption.

### BRIEF DESCRIPTION OF DRAWINGS

FIG. 1 is a block diagram illustrating an example when a rectifier circuit and a conversion unit of a power receiver of a wireless power supply system in the first embodiment are electrically disconnected.

FIG. 2 is a block diagram illustrating an example when the rectifier circuit and the conversion unit of the power receiver of the wireless power supply system in the first embodiment are electrically connected.

FIG. 3 is a graph showing an example of the relationship between open-circuit voltage and input power in the first embodiment.

FIG. 4 is a flowchart showing an example operation in a test mode of the power receiver in the first embodiment.

FIG. 5 is a diagram illustrating an example of a power receiving antenna of the power receiver in the second embodiment.

FIG. 6 is an example block diagram when the power receiver in the second embodiment is in a charging mode.

FIG. 7 is an example block diagram when the power receiver in the third embodiment is in a test beam mode.

### DESCRIPTION OF EMBODIMENTS

### Summary of the embodiments

The power receiver in the embodiments is generally composed of a power receiving antenna that receives a power transfer signal transmitted from a power transmitter; a rectifier circuit that converts AC input power output from the power receiving antenna based on the power transfer signal into DC received power; a conversion unit that converts the received power output from the rectifier circuit so as to be suitable for control in a subsequent stage; a measurement unit that measures received-power voltage of the received power output from the rectifier circuit; a switching unit that switches between electrical connection and disconnection of the rectifier circuit and the conversion unit; and a power reception control unit that estimates the input power based on the received-power voltage that is measured by the measurement unit when the rectifier circuit and the conversion unit are disconnected.

This power receiver estimates the received input power based on the voltage of the received power after rectification. Therefore, compared to when inserting a measurement circuit into a high-frequency transmission line, the received input power can be estimated while suppressing power consumption.

### First embodiment

### General configuration of a power receiver 3

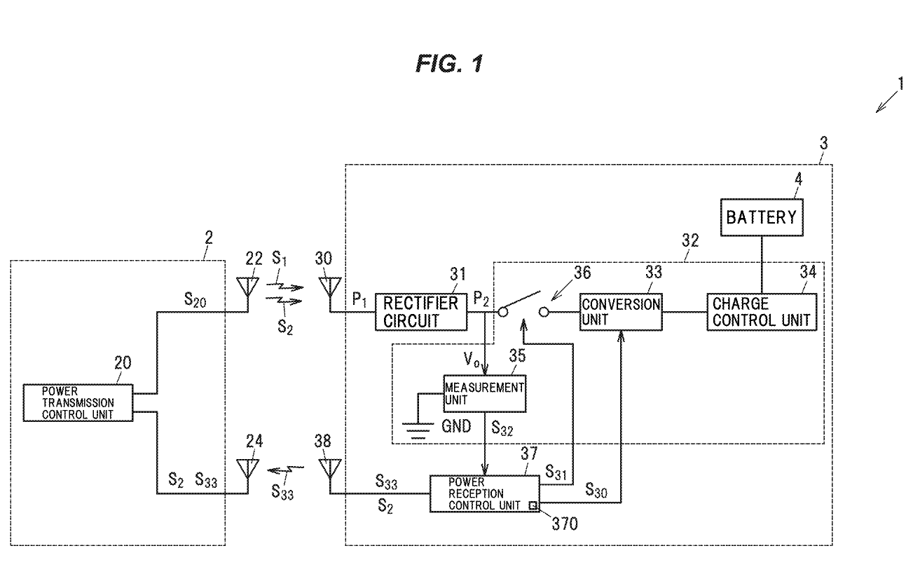

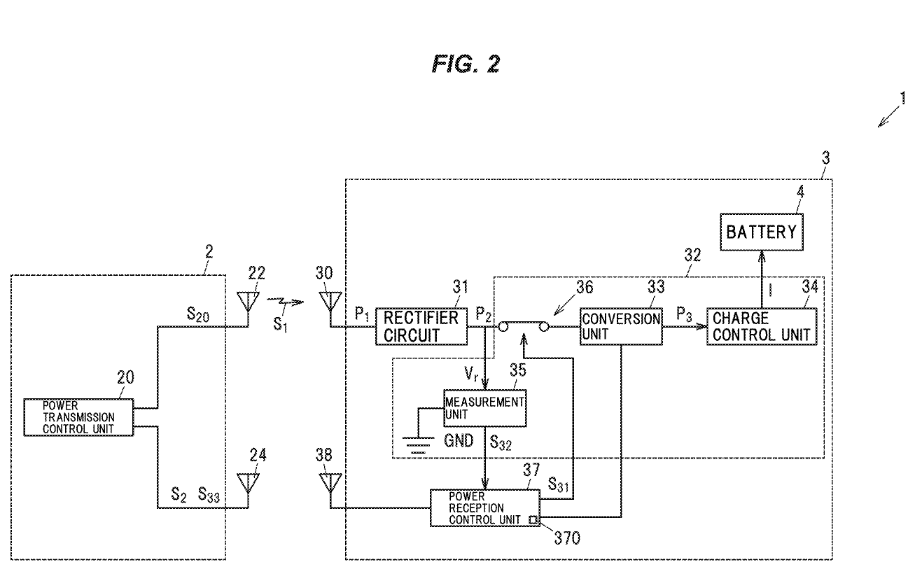

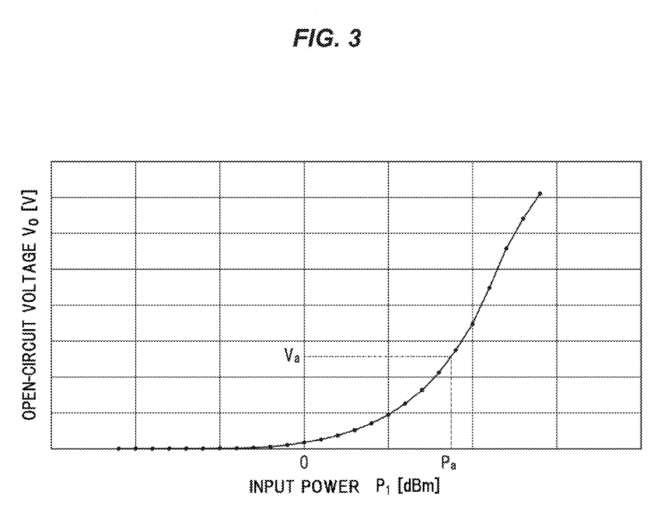

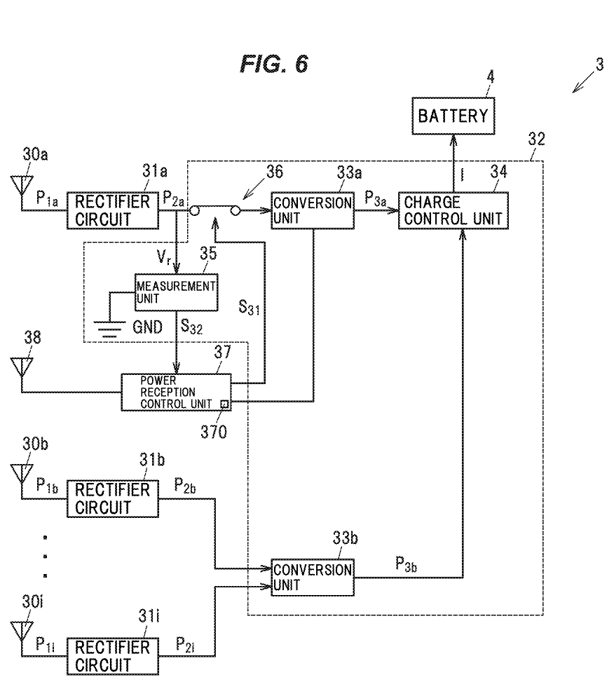

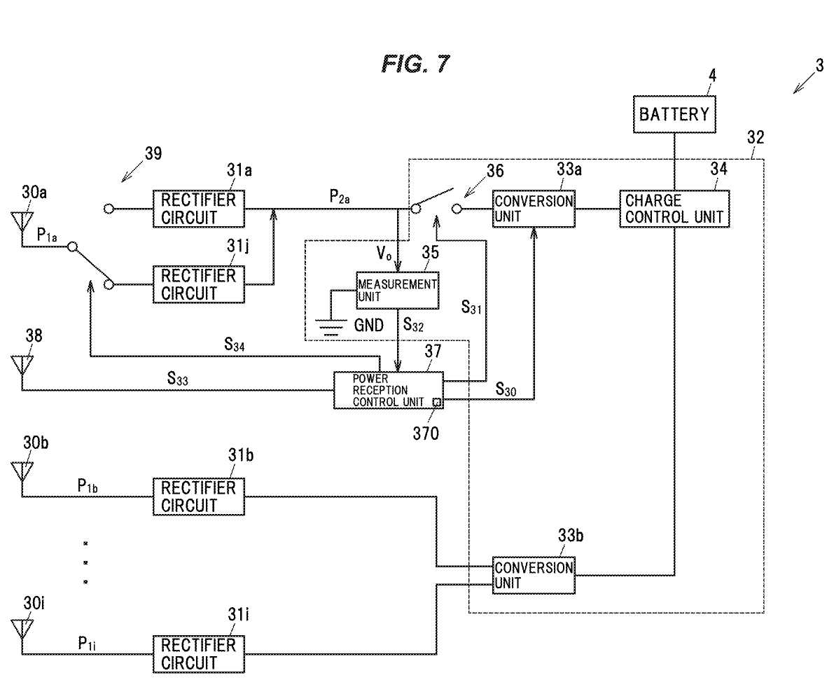

FIG. 1 is a block diagram illustrating an example when a rectifier circuit and a conversion unit of a power receiver of a wireless power supply system in the first embodiment are electrically disconnected. FIG. 2 is a block diagram illustrating an example when the rectifier circuit and the conversion unit of the power receiver of the wireless power supply system in the first embodiment are electrically connected. FIG. 3 is a graph showing an example of the relationship between open-circuit voltage and input power in the first embodiment. In FIGS. 1 and 2, and also in FIGS. 6 and 7 described later, flows of main power, signals and information are indicated by arrows. In addition, in FIG. 3, the horizontal axis indicates input power P₁ [dBm] and the vertical axis indicates open-circuit voltage Vₒ [V]. First, a general configuration of a wireless power supply system 1 will be described below.

As shown in FIGS. 1 and 2, the wireless power supply system 1 includes, e.g., a power transmitter 2 and at least one power receiver 3.

As shown in FIGS. 1 and 2, the power receiver 3 is generally composed of a power receiving antenna 30 that receives a power transfer signal S₁ transmitted from the power transmitter 2, a rectifier circuit 31 that converts AC input power P₁ output from the power receiving antenna 30 based on the power transfer signal S₁ into DC received power P₂, a conversion unit 33 that converts the received power P₂ output from the rectifier circuit 31 so as to be suitable for control in a subsequent stage, a measurement unit 35 that measures received-power voltage of the received power P₂ output from the rectifier circuit 31, a switching unit 36 that switches between electrical connection and disconnection of the rectifier circuit 31 and the conversion unit 33, and a power reception control unit 37 that estimates the input power P₁ based on the received-power voltage that is measured by the measurement unit 35 when the rectifier circuit 31 and the conversion unit 33 are disconnected.

The control in the subsequent stage in the first embodiment is charge control of a battery 4, but is not limited thereto. When having a load other than the battery 4, it is drive control of this load.

As shown in FIG. 1, the measurement unit 35 is electrically connected to ground GND and measures open-circuit voltage Vₒ as the received-power voltage when the rectifier circuit 31 and the conversion unit 33 are disconnected.

The power reception control unit 37 has associating information 370 associating the open-circuit voltage Vₒ with the input power P₁, and estimates the input power P₁ based on the measured open-circuit voltage Vₒ and the associating information 370.

The power reception control unit 37 controls the conversion unit 33 according to an optimal combination of voltage and current based on the estimated input power P₁.

The power receiver 3 includes the battery 4 and a charge control unit 34 that controls charging of the battery 4. The conversion unit 33, the charge control unit 34, the measurement unit 35, and the switching unit 36 constitute a charge control circuit 32. This charge control circuit 32 is integrated into an IC (Integrated Circuit) together with, e.g., the power reception control unit 37.

The battery 4 is, e.g., a lead-acid battery, a nickel-metal hydride battery, a lithium-ion battery, and a sodium-sulfur battery, etc. For the power receiver 3, e.g., plural batteries 4 may be included or the battery 4 may be removable.

### Configuration of the power transmitter 2

As shown in FIGS. 1 and 2, the power transmitter 2 is generally composed of, e.g., a power transmission control unit 20, a power transmitting antenna 22, and a power transmitting-communication antenna 24. By performing phase control, the power transmitter 2 transmits the power transfer signal S₁ optimal for the power receiver 3.

The power transmission control unit 20 is, e.g., a microcomputer composed of a CPU (Central Processing Unit) performing calculation and processing, etc., of the acquired data according to a stored program, and a RAM (Random Access Memory) and a ROM (Read Only Memory) as semiconductor memories, etc. The ROM stores, e.g., a program for operation of the power transmission control unit 20. The RAM is used as, e.g., a storage area to temporarily store calculation results, etc. The power transmission control unit 20 also has, inside thereof, a means to generate a clock signal and operates based on the clock signal.

The power transmission control unit 20 outputs a high-frequency power transmission signal S₂₀, which has been amplified under phase control and from which unwanted frequency components such as noise have been removed, to the power transmitting antenna 22.

The power transmitting antenna 22 transmits the power transmission signal S₂₀ as, e.g., the power transfer signal S₁ or a test beam S₂. This power transmitting antenna 22 is a phased array antenna, as an example.

The power transmitting-communication antenna 24 is composed of, e.g., plural microstrip antennas (planar antennas). The power transmitting-communication antenna 24 receives input power information S₃₃ from the power receiver 3.

Based on the input power information S₃₃, the power transmission control unit 20 performs beam steering to perform optimization of concentrating the power transfer signal S₁ so that the input power P₁ is maximized.

### Configuration of the power receiver 3

As shown in FIGS. 1 and 2, the power receiver 3 is generally composed of the power receiving antenna 30, the rectifier circuit 31, the charge control circuit 32, the power reception control unit 37, a power receiving-communication antenna 38, and the battery 4.

The power receiving antenna 30 is, e.g., at least one microstrip antenna. The power receiving antenna 30 receives the power transfer signal S₁ and outputs it as the AC input power P₁ to the rectifier circuit 31.

The rectifier circuit 31 converts the AC input power P₁ into the received power P₂ which is DC power. The rectifier circuit 31 is arranged on the back side of the power receiving antenna 30 to minimize the length of the high-frequency transmission line. The charge control circuit 32 and the power reception control unit 37 are also arranged on the back side of the power receiving antenna 30 in a similar manner to the rectifier circuit 31.

The conversion unit 33 is a DC (Direct Current)-DC circuit that converts the received power P₂ into a voltage suitable for charging the battery 4. The conversion unit 33 outputs charging power P₃ with the converted voltage to the charge control unit 34.

The conversion unit 33 includes at least an MPPT (Maximum Power Point Tracking) control circuit, and generates and outputs a charging current I that is optimum for charging the battery 4. The conversion unit 33 may be configured to also include an MPPC (Maximum Power Point Control) control circuit and/or a PWM (Pulse Width Modulation) control circuit, etc. in addition to the MPPT control circuit and switch between these control circuits based on a control signal S₃₀ output from the power reception control unit 37.

The measurement unit 35 is provided in advance in, e.g., the charge control circuit 32 to perform MPPT control, etc. The measurement unit 35 constantly measures received-power voltage Vᵣ of the received power P₂. When the electrical connection between the rectifier circuit 31 and the conversion unit 33 is cut off, the measurement unit 35 measures the open-circuit voltage Vₒ as the received-power voltage Vᵣ of the received power P₂ because the measurement unit 35 is connected to the ground. The measurement unit 35 outputs the measured received-power voltage Vᵣ as a received-power voltage signal S₃₂ to the power reception control unit 37. The measurement unit 35 outputs the received-power voltage Vᵣ as an analog value, but it is not limited thereto. The measurement unit 35 may be configured to have an A/D conversion circuit and output a digital value.

The switching unit 36 is arranged between the rectifier circuit 31 and the conversion unit 33. The switching unit 36 switches between the electrical connection and disconnection of the rectifier circuit 31 and the conversion unit 33 based on a switching signal S₃₁ output from the power reception control unit 37. The switching unit 36 may be configured to switch the electrical connection between the rectifier circuit 31 and the conversion unit 33, and the electrical connection between the rectifier circuit 31 and the measurement unit 35.

The power reception control unit 37 is, e.g., a microcomputer composed of a CPU, a RAM, and a ROM, etc. The ROM stores, e.g., a program for operation of the power reception control unit 37. The RAM is used as, e.g., a storage area to temporarily store calculation results, etc. The power reception control unit 37 also has, inside thereof, a means to generate a clock signal and operates based on the clock signal.

As shown in FIG. 1, in the test beam mode in which the test beam S₂ is input from the power transmitter 2, the power reception control unit 37 controls the switching unit 36 to cut off the electrical connection between the rectifier circuit 31 and the conversion unit 33, i.e., to disconnect them, and causes the measurement unit 35 to measure the open-circuit voltage Vₒ of the received power P₂.

Then, as shown in FIG. 2, in the charging mode to charge the battery 4, the power reception control unit 37 controls the switching unit 36 to electrically connect the rectifier circuit 31 to the conversion unit 33. At this time, the measurement unit 35 measures the received-power voltage Vᵣ.

The power reception control unit 37 has an A/D conversion circuit that converts the received-power voltage Vᵣ and the open-circuit voltage Vₒ, which are the analog values of output from the measurement unit 35, into digital values. Since the measurement unit 35 constantly measures the voltage of the received power P₂, the measurement unit 35 outputs the received-power voltage signal S₃₂ indicating the voltage value of either the received-power voltage Vᵣ or the open-circuit voltage Vₒ to the power reception control unit 37.

In this regard, the test beam mode and the charging mode may be, e.g., switched periodically, or may be configured in such a manner that the power receiver 3 is in the test beam mode when the power is turned on, and the charging mode continues after the input power P₁ is estimated until the power receiver 3 is turned off.

The received power P₂ rectified by rectifier circuit 31 is different for each rectifier circuit 31, even when the input power P₁ is the same. The power reception control unit 37 has the associating information 370 associating the open-circuit voltage Vₒ corresponding to the rectifier circuit 31 with the input power P₁, and estimates the input power P₁ based on the measured open-circuit voltage Vₒ and the associating information 370.

When, e.g., open-circuit voltage Vₐ is measured, the power reception control unit 37 estimates that input power Pₐ corresponding to the open-circuit voltage Vₐ is the input power P₁ as shown in FIG. 3. During the test beam mode, the power reception control unit 37 generates the input power information S₃₃, which is information about the estimated input power P₁, and outputs it to the power transmitter 2 through the power receiving-communication antenna 38.

The power receiving-communication antenna 38 is, e.g., a microstrip antenna. During the test beam mode, the power receiving-communication antenna 38 transmits the input power information S₃₃.

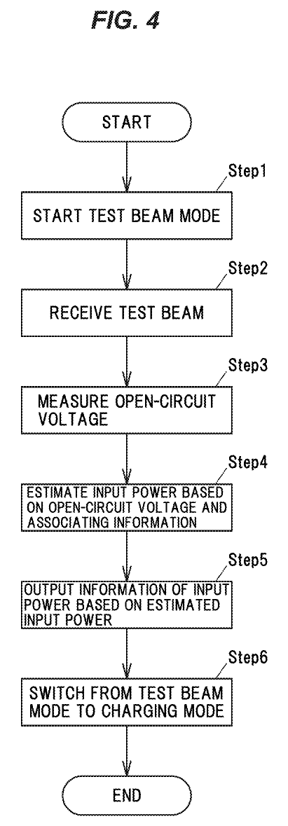

An example operation of the power receiver 3 during the test beam mode in the first embodiment will be described below with reference to the flowchart of FIG. 4.

### Operation

As shown in FIG. 1, the power reception control unit 37 of the power receiver 3 outputs the switching signal S₃₁ to the switching unit 36 to electrically disconnects the rectifier circuit 31 from the conversion unit 33, and starts the test beam mode (Step 1).

The power reception control unit 37 receives the test beam S₂ from the power transmitter 2 (Step 2).

By electrically disconnecting the rectifier circuit 31 from the conversion unit 33, the power reception control unit 37 causes the measurement unit 35 to measure the open-circuit voltage Vₒ of the received power P₂ (Step 3).

The power reception control unit 37 acquires the received-power voltage signal S₃₂ relating to the open-circuit voltage Vₒ of the received power P₂ from the measurement unit 35, and estimates the input power P₁ based on the open-circuit voltage Vₒ and the associating information 370 (Step 4).

The power reception control unit 37 generates the input power information S₃₃ relating to the estimated input power P₁ and outputs it to the power transmitter 2 through the power receiving-communication antenna 38 (Step 5). Here, the power reception control unit 37 generates the control signal S₃₀ based on the estimated input power P₁ and outputs it to the conversion unit 33.

As shown in FIG. 2, the power reception control unit 37 outputs the switching signal S₃₁ to the switching unit 36 and electrically connects the rectifier circuit 31 to the conversion unit 33 to switch from the test beam mode to the charging mode (Step 6), and ends the test beam mode.

### Effects of the first embodiment

The power receiver 3 in the first embodiment can estimate the received input power P₁ while suppressing power consumption. In particular, the power receiver 3 estimates the received input power P₁ based on the open-circuit voltage Vₒ of the rectified received power P₂. Therefore, compared to when inserting a measurement circuit, etc. into the high-frequency transmission line, the received input power P₁ can be estimated while minimizing power loss caused by the insertion.

In the power receiver 3, the open-circuit voltage Vₒ of the received power P₂ rectified by the rectifier circuit 31 is measured by the measurement unit 35 that is provided in advance in the charge control circuit 32. Therefore, compared to when measuring using a combination of an RF power meter (Radio Frequency Power Meter) and a switch, there is no need to newly add any electronic components and manufacturing costs are suppressed.

In the power receiver 3, the open-circuit voltage Vₒ of the received power P₂ output from the rectifier circuit 31 is measured. Therefore, compared to when this configuration is not adopted, power consumption is suppressed and power reception efficiency is improved.

The power receiver 3 can optimize MPPT control, etc. using the estimated input power P₁. Therefore, compared to when this configuration is not adopted, it is possible to maximize power reception efficiency at low cost.

The power receiver 3 estimates the input power P₁ using the associating information 370 according to the characteristics of the rectifier circuit 31. Therefore, compared to when this configuration is not adopted, estimation accuracy is higher.

The receiving device 3 transmits the input power information S₃₃ relating to the estimated input power P₁ to the power transmitter 2. Therefore, compared to when this configuration is not adopted, power transmission efficiency of the wireless power supply system 1 can be improved by optimizing the power transfer signal S₁ in the power transmitter 2.

### Second embodiment

The second embodiment differs from the first embodiment in that one antenna of the multi-rectenna is electrically connected to the measurement unit.

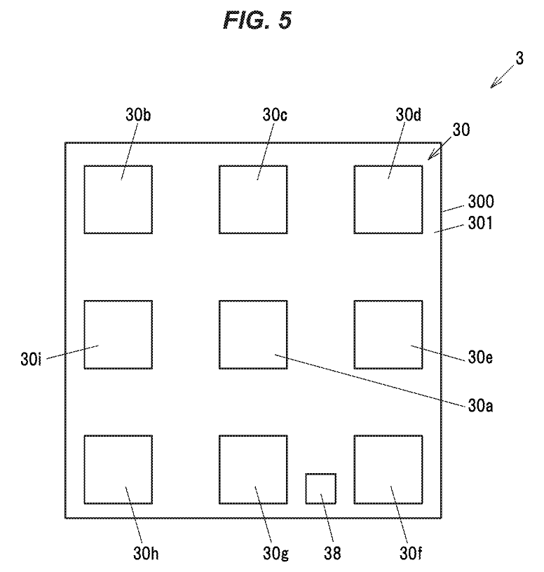

FIG. 5 is a diagram illustrating an example of the power receiving antenna of the power receiver in the second embodiment. FIG. 6 is an example block diagram when the power receiver in the second embodiment is in the charging mode. In the embodiments described below, portions having the same functions and configurations as those in the first embodiment are denoted by the same reference signs as those in the first embodiment, and the explanation thereof will be omitted.

As shown in FIGS. 5 and 6, the power receiving antenna 30 has plural antennas, and at least one of the plural antennas is electrically connected to the measurement unit 35. The power receiving antenna 30 is, e.g., a multi-rectenna.

The power receiver 3 in the second embodiment includes two types of conversion units: a conversion unit 33a electrically connected to an antenna 30a which is used in the test beam mode and in the charging mode, and a conversion unit 33b electrically connected to antennas 30b to 30i which are used in the charging mode. The antenna 30a is used as a channel for beam scanning.

The power receiving antenna 30 in the second embodiment includes the antennas 30a to 30i as an example, but is not limited to this. The antennas 30a to 30i are arranged in a grid pattern at equal intervals on a surface 301 of a housing 300 as shown in FIG. 5, but are not limited thereto.

In the power receiver 3, the antenna 30a is arranged at the center and the antennas 30b to 30i are arranged therearound. The power receiving-communication antenna 38 is arranged between the antenna 30f and the antenna 30g as an example, but is not limited thereto.

As shown in FIG. 6, the antenna 30a is electrically connected to the rectifier circuit 31a. This rectifier circuit 31a is electrically connected to the measurement unit 35 and is also electrically connected to the conversion unit 33a through the switching unit 36. The rectifier circuit 31a converts input power P₁ₐ received by the antenna 30a into received power P₂ₐ. The conversion unit 33a converts the received power P₂ₐ into charging power P₃ₐ and outputs it to the charge control unit 34.

During the test beam mode, the power reception control unit 37 controls the switching unit 36 to electrically disconnect the rectifier circuit 31a from the converter unit 33a and measures the open-circuit voltage Vₒ by the measurement unit 35. The power reception control unit 37 estimates the input power P₁ₐ based on the measured open-circuit voltage Vₒ and the associating information 370. The power reception control unit 37 generates the input power information S₃₃ based on the estimated input power P₁ₐ and outputs it to the power transmitter 2 through the power receiving-communication antenna 38.

As shown in FIG. 6, the antennas 30b to 30i are electrically connected to rectifier circuits 31b to 31i. The rectifier circuits 31b to 31i output received power P_{2b} to P₂ᵢ to the conversion unit 33b. The conversion unit 33b converts the received power P_{2b} to P₂ᵢ into charging power P_{3b} and outputs it to the charge control unit 34. The antennas 30b to 30i receive the power transfer signal S₁ and output input power P_{1b} to P₁ᵢ respectively to the rectifier circuits 31b to 31i.

The rectifier circuits 31a to 31i are arranged on the back side of the antennas 30a to 30i to minimize the length of the high-frequency transmission line. The charge control circuit 32 and the power reception control unit 37 are arranged on the back side of the antennas 30a to 30i in a similar manner to the rectifier circuits 31a to 31i.

The charge control unit 34 generates the charging current I based on the charging power P₃ₐ and the charging power P_{3b}, and charges the battery 4.

As a modification, the power receiver 3 may measure the open-circuit voltage Vₒ based on the received power P₂ for each of the plural antennas and estimate the input power P₁.

### Effects of the second embodiment

The power receiver 3 in the second embodiment estimates the input power P₁ using one antenna 30a among the antennas 30a to 30i. Therefore, compared to when using all the antennas, power consumption is suppressed and power reception control can be performed efficiently.

The power receiver 3 uses the centrally located antenna 30a during the test beam mode. Therefore, compared to when using other antennas, the power receiver 3 receives the power transfer signal S₁ more efficiently and the estimation accuracy is higher.

### Third embodiment

The third embodiment differs from the other embodiments in that it is configured to switch the rectifier circuits during the test beam mode.

FIG. 7 is an example block diagram when the power receiver in the third embodiment is in the test beam mode. As shown in FIG. 7, the power receiver 3 in the third embodiment further includes a rectifier circuit 31j, and a circuit switching unit 39 that switches the connection between the rectifier circuit 31a and the rectifier circuit 31j.

The rectifier circuit 31j supports a lower input power P₁ₐ than the rectifier circuit 31a. When the power receiver 3 is in the test beam mode, the power transmitter 2 does not transmit the power transfer signal S₁ with high power, and at first transmits the power transfer signal S₁ with low power. The rectifier circuits 31a to 31i are configured to not perform conversion into received power when the input power P₁ₐ to P₁ᵢ based on the power transfer signal S₁ with low power is input.

During the test beam mode, the power reception control unit 37 outputs a circuit switching signal S₃₄ and controls the circuit switching unit 39 to electrically connect the antenna 30a to the rectifier circuit 31j so that the rectifier circuit 31j rectifies the input power P₁ₐ.

During the charging mode, the power reception control unit 37 outputs the circuit switching signal S₃₄ and controls the circuit switching unit 39 to electrically connect the antenna 30a to the rectifier circuit 31a so that the rectifier circuit 31a rectifies the input power P₁ₐ.

### Effects of the third embodiment

The power receiver 3 in the third embodiment can switch between the rectifier circuit 31j used during the test beam mode and the rectifier circuit 31a used during the charging mode. Therefore, compared to when this configuration is not adopted, it is possible to suppress the situation in which the power transfer signal S₁ is a low output and cannot be converted into the received power P₂ₐ.

According to the power receiver 3 in at least one of the above-described embodiments, it is possible to estimate the received input power P₁ while suppressing power consumption.

The power receiver 3 in the above-described embodiments and modifications may be, e.g., partially realized by a program executed by a computer, an ASIC (Application Specific Integrated Circuit), and an FPGA (Field Programmable Gate Array), etc. according to the application.

Although the embodiments and modifications of the invention have been described, these embodiments and modifications are merely examples and the invention according to claims is not to be limited thereto. These new embodiments and modifications may be implemented in various other forms, and various omissions, substitutions and changes, etc., can be made without departing from the gist of the invention. In addition, not all combinations of the features described in these embodiments and modifications are necessary to solve the problem of the invention. Further, these embodiments and modifications are included within the scope and gist of the invention and also within the invention described in the claims and the range of equivalency.

### REFERENCE SIGNS LIST

1 WIRELESS POWER SUPPLY SYSTEM
2 POWER TRANSMITTER
3 POWER RECEIVER
4 BATTERY
20 POWER TRANSMISSION CONTROL UNIT
22 POWER TRANSMITTING ANTENNA
24 POWER TRANSMITTING-COMMUNICATION ANTENNA
30 POWER RECEIVING ANTENNA
30a – 30i ANTENNA
31a – 30j RECTIFIER UNIT
32 CHARGE CONTROL CIRCUIT
33, 33a, 33b CONVERSION UNIT
34 CHARGE CONTROL UNIT
35 MEASUREMENT UNIT
36 SWITCHING UNIT
37 POWER RECEPTION CONTROL UNIT
38 POWER RECEIVING-COMMUNICATION ANTENNA
39 CIRCUIT SWITCHING UNIT
300 HOUSING
301 SURFACE
370 ASSOCIATING INFORMATION
I CHARGING CURRENT
P₁, P₁ₐ – P₁ᵢ INPUT POWER
P₂, P₂ₐ – P₂ᵢ RECEIVED POWER
P₃, P₃ₐ – P₃ᵢ CHARGING POWER
Pₐ INPUT POWER
S₁POWER TRANSFER SIGNAL
S₂ TEST BEAM
S₂₀ POWER TRANSMISSION SIGNAL
S₃₀ CONTROL SIGNAL
S₃₁ SWITCHING SIGNAL
S₃₂ RECEIVED-POWER VOLTAGE SIGNAL
S₃₃ INPUT POWER INFORMATION
S₃₄ CIRCUIT SWITCHING SIGNAL
Vₐ, Vₒ OPEN-CIRCUIT VOLTAGE
Vᵣ RECEIVED-POWER VOLTAGE

1. A power receiver, comprising:
a power receiving antenna that receives a power transfer signal transmitted from a power transmitter;
a rectifier circuit that converts AC input power output from the power receiving antenna based on the power transfer signal into DC received power;
a conversion unit that converts the received power output from the rectifier circuit so as to be suitable for control in a subsequent stage;
a measurement unit that measures received-power voltage of the received power output from the rectifier circuit;
a switching unit that switches between electrical connection and disconnection of the rectifier circuit and the conversion unit; and
a power reception control unit that estimates the input power based on the received-power voltage that is measured by the measurement unit when the rectifier circuit and the conversion unit are disconnected.

2. The power receiver according to claim 1, wherein the measurement unit is electrically connected to ground and measures open-circuit voltage as the received-power voltage when the rectifier circuit and the conversion unit are disconnected.

3. The power receiver according to claim 2, wherein the power reception control unit has associating information associating the open-circuit voltage with the input power, and estimates the input power based on the measured open-circuit voltage and the associating information.

4. The power receiver according to claim 3, wherein the power reception control unit controls the conversion unit according to an optimal combination of voltage and current based on the estimated input power.

5. The power receiver according to claim 1, wherein the power receiving antenna comprises a plurality of antennas, and at least one of the plurality of antennas is electrically connected to the measurement unit.
